(19) United States
(12) Patent Application Publication
(10) Pub. No.: US 2007/0236239 A1
(43) Pub. Date: Oct. 11, 2007

(54) INTEGRATED CIRCUIT HAVING A SEMICONDUCTOR DEVICE AND INTEGRATED CIRCUT TEST METHOD

(75) Inventor: Thorsten Bucksch, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/685,537

(22) Filed: Mar. 13, 2007

(30) Foreign Application Priority Data
Mar. 14, 2006 (DE) 10 2006 011 706.9

(51) Int. Cl. G01R 31/26

(52) U.S. Cl. 324/765

(57) ABSTRACT

An integrated circuit having a semiconductor device an integrated circuit test method for testing a semiconductor device is disclosed. In a normal operation mode of the semiconductor device, a signal present at a connection of the semiconductor device is transmitted to a circuit core of the semiconductor device, and in a test operation mode of the semiconductor device, a test signal present at the connection of the semiconductor device is transmitted to a further connection of the semiconductor device instead to the circuit core of the semiconductor device.

### CROSS-REFERENCE TO RELATED APPLICATIONS

This Utility Patent Application claims priority to German Patent Application No. DE 10 2006 011 706.9 filed on Mar. 14, 2006, which is incorporated herein by reference.

### BACKGROUND

The invention relates to an integrated circuit having a semiconductor device and to an integrated circuit test method.

Semiconductor devices, e.g., corresponding, integrated (analog or digital) computing circuits, semiconductor memory devices such as functional memory devices (PLAs, PALs, etc.) and table memory devices (e.g., ROMs or RAMs, in particular SRAMs and DRAMs), etc. are subject to comprehensive tests in the course of their manufacturing process.

For the common manufacturing of a plurality of (in general identical) semiconductor devices, a wafer (i.e. a thin disc consisting of monocrystalline silicon) is used. The wafer is processed appropriately (e.g., successively subject to a plurality of coating, exposure, etching, diffusion, and implantation processes, etc.), and subsequently e.g., sawn apart (or e.g., scratched and broken), so that the individual devices are then available.

During the manufacturing of semiconductor devices (e.g., of DRAMS (Dynamic Random Access Memories or dynamic write-read memories, respectively), in particular of DDR-DRAMs (Double Data Rate—DRAMs)), the (semi-finished) devices (that are still positioned on the wafer) may—even before all the desired, above-mentioned processing steps were performed at the wafer—(i.e. already in a semi-finished state of the semiconductor devices) be subject to appropriate test methods (e.g., kerf measurements at the wafer kerf) at one or a plurality of test stations by using one or a plurality of test devices.

After the finishing of the semiconductor devices (i.e. after the performing of all the above-mentioned wafer processing), the semiconductor devices are subject to further test methods at one or a plurality of (further) test stations—the finished devices that are still positioned on the wafer may, for instance, be correspondingly tested by using appropriate (further) test devices (“disc tests”).

Correspondingly, one or a plurality of further tests may be performed (at appropriate further test stations, using appropriate, further test devices) e.g., after the incorporation of the semiconductor devices in the corresponding semiconductor device packages, and/or e.g., after the incorporation of the semiconductor device package (along with the respective semiconductor devices incorporated therein) in corresponding electronic modules (“module tests”).

When testing semiconductor devices, “DC tests” and/or “AC tests” may, for instance, be used as test methods (e.g., with the above-mentioned disc tests, module tests, etc.).

In a DC test, a voltage (or current) of particular—especially constant—intensity may, for instance, be applied to a corresponding connection of a semiconductor device to be tested, and then the intensity of—resulting—currents (or voltages) may be measured—in particular it may be examined whether these currents (or voltages) range within predetermined, desired threshold values.

Contrary to this, in an AC test, voltages (or currents)—varying in intensity—may, for instance, be applied to corresponding connections of a semiconductor device, in particular corresponding test pattern signals (“patterns”) by which appropriate function tests may be performed at the respective semiconductor device.

By the above-mentioned test methods it is possible to identify and then sort out (or partially also repair) defective semiconductor devices or modules, respectively, and/or—corresponding to the test results achieved—to correspondingly modify or optimally adjust, respectively, the process parameters used during the manufacturing of the devices, etc.

By using the above-mentioned test methods it is, for instance, possible to test whether the interface circuits provided on a corresponding semiconductor device, e.g., receiver circuits, driver circuits, etc. connected with corresponding semiconductor device connections function correctly.

Interface circuits that do not function correctly are—in particular in the case of devices operating with high internal or external data rates—a relatively frequent reason of errors.

In the case of conventional function tests, corresponding test data can be stored by an appropriate test device in a semiconductor device to be tested, and be read out later again. Subsequently, the test device may examine whether the data stored in the semiconductor device correspond to the data read out from the semiconductor device.

As test data, corresponding pseudo random test data may, for instance, be used.

By the use of pseudo random test data it can be achieved that a relatively great number of different frequency shares occurs in the test data signals present at the corresponding data lines, or that the test data signals consist of a relatively broad-band frequency mixture, respectively.

In the case of conventional function tests, the above-mentioned test pattern signals—i.e. corresponding data, address, clock, and control signals—applied to the connections of a semiconductor device by a corresponding test device have to be protocol-compliant.

It is of disadvantage that, with new or modified protocols—e.g., a new semiconductor device generation—appropriate test devices, as a rule, enter the market with a time delay only, and are relatively expensive.

For these and other reasons, there is a need for the present invention.

### SUMMARY

One embodiment provides a method for testing an integrated circuit having a semiconductor device including defining a normal operation mode and a test operation mode. A signal present at a connection of the semiconductor device to a circuit core of the semiconductor device in the normal operation mode, and a test signal present at the connection of the semiconductor device to a further connection of the semiconductor device instead to the circuit core of the semiconductor device in the test operation mode is transmitted.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic representation of a test system in accordance with an embodiment of the present invention.

FIG. 2 illustrates a schematic detailed representation of a section of a semiconductor device adapted to be tested by using the test system illustrated in FIG. 1.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In one embodiment, the invention provides a novel integrated circuit having semiconductor device and a novel integrated circuit test method, in particular a device and a method by which the above-mentioned and/or further disadvantages of conventional devices or methods can be overcome at least partially.

In one embodiment, the invention provides a semiconductor device test method for testing a semiconductor device, wherein, in a normal operation mode of the semiconductor device, a signal present at a connection of the semiconductor device is transmitted to a circuit core of the semiconductor device, and wherein, in a test operation mode of the semiconductor device, a test signal present at the connection of the semiconductor device is transmitted to a further connection of the semiconductor device instead to the circuit core of the semiconductor device.

In another embodiment, the invention provides a semiconductor device including a connection, wherein, in a normal operation mode of the semiconductor device, a signal present at the connection is transmitted to a circuit core of the semiconductor device, wherein the semiconductor device additionally includes a switch for transmitting a test signal present at the connection to a further connection of the semiconductor device instead to the circuit core of the semiconductor device in a test operation mode of the semiconductor device.

The switching may, for instance, be connected between an interface circuit of a semiconductor device and the circuit core of the semiconductor device.

By transmitting the test signal present at the connection to the further connection of the semiconductor device instead to the semiconductor device circuit core, the semiconductor device, in particular the interface circuit provided there, can be subject to a corresponding test in a simple manner—for instance, in that a bit sequence input as test signal at the connection is compared with a bit sequence output at the further connection in reaction to the input bit sequence.

The test system 1 includes a test device 4, a pattern generator 3, and a semiconductor device 2 to be tested and arranged in a corresponding semiconductor device package.

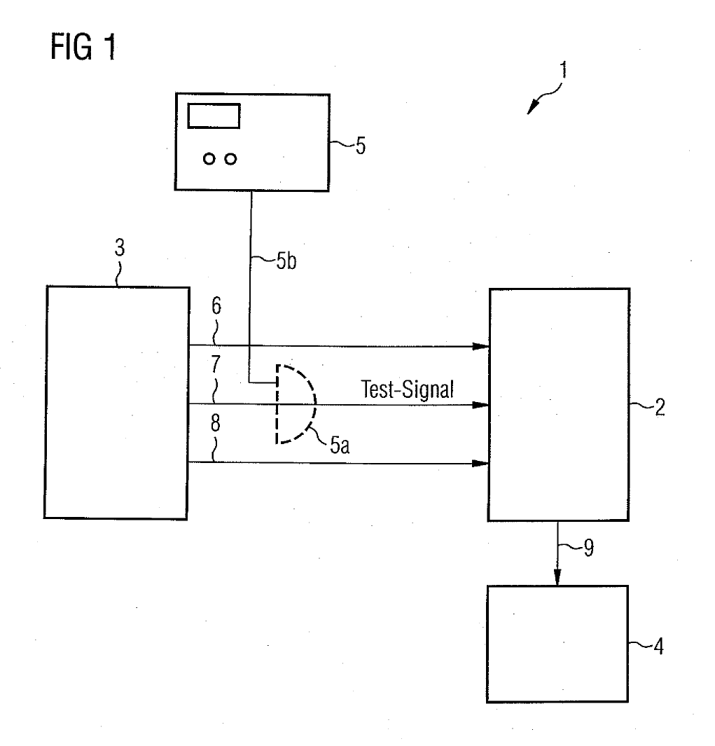

Instead of testing a (single) device 2 arranged in a corresponding semiconductor device package, a test system corresponding to the test system 1 illustrated in FIG. 1 may, for instance, also be used for testing semi-finished or finished devices that are still positioned on a corresponding wafer, and/or, for instance, for testing an electronic module including a plurality of semiconductor devices incorporated in corresponding device packages, etc.

The integrated circuit semiconductor device 2 illustrated in FIG. 1 may, for instance, be an integrated (analog or digital) computing circuit, and/or e.g., a semiconductor memory device such as a functional memory device (PLA, PAL, etc.) or table memory device (e.g., ROM or RAM, in particular SRAM or DRAM), in particular a DRAM (Dynamic Random Access Memory or dynamic write-read memory), e.g., DDR-DRAM (Double Data Rate—DRAM).

As results from FIG. 1, the pattern generator 3 outputs a test signal at a test line 7 (and additionally at one or a plurality of further lines).

Optionally, the pattern generator 3 may additionally—as is illustrated in FIG. 1 and as will be explained in more detail in the following—output corresponding interference signals at one or a plurality of test lines 6, 8 adjacent to the test line 7 (here: at the test lines 6, 8 that are directly adjacent to the test line 7).

The function of the test device 4 and of the pattern generator 3 illustrated in FIG. 1 may, not illustrated embodiments, also be fulfilled by one single (test) device.

The pattern generator 3 may be any pattern generator 3, e.g., a pseudo random pattern generator 3 generating corresponding pseudo random test data (i.e. a stochastic bit sequence) as test and interference signals, or e.g., a pattern generator 3 of a BERT (BERT=Bit Error Rate Tester) (which, for instance, does not generate any pseudo random test data, but e.g., corresponding test and interference signals that change regularly or predictably between a state “Zero” and a state “One”, i.e. a determinate bit sequence).

The test and/or interference signals may be transmitted with a relatively high data rate, e.g., more than 1 GB/s (e.g., 7 GB/s or 13 GB/s, etc.). The respective data rate to be used by the pattern generator 3 may be adjusted flexibly variable.

If corresponding pseudo random test data are used as test and/or interference signals, it can be achieved that a relatively great number of different frequency shares occurs in the test and/or interference signals present at the corresponding lines 6, 7, 8, or that the test and/or interference signals consist of a relatively broad-band frequency mixture, respectively.

By using the above-mentioned interference signals applied to the test lines 6, 8, corresponding crosstalk interferences of the test signal present at the test line 7 can be simulated, i.e. an influencing of the test line 7 (or of the test signal present there, respectively)—based on couplings via corresponding magnetic/electric fields—by using (interference) signals present at neighbor lines (here: the test lines 6, 8).

Additionally to the above-mentioned crosstalk interferences of the test signal caused by the above-mentioned interference signals, the test signal may, for instance, be impacted with a corresponding jitter—that is deliberately caused additionally—(e.g., with a corresponding determinate and/or stochastic jitter), for instance, in that, by a corresponding means 5a, e.g., a power divider, a jitter signal provided by a jitter source 5 at a line 5b is mixed into the test signal present at the test line 7.

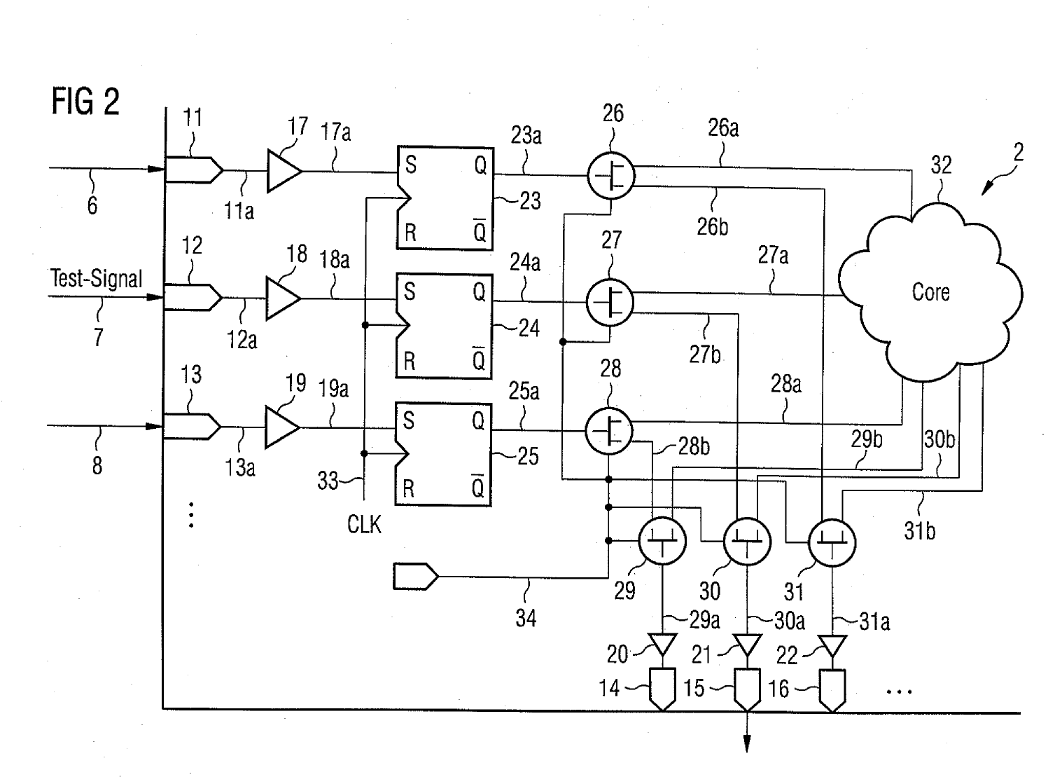

As will be explained in more detail in the following, the test signal output by the pattern generator 3 is, in accordance with FIG. 2, transmitted to a corresponding pin of the semiconductor device 2, and from there—via a corresponding bonding wire—to a corresponding connection 12 of the semiconductor device 2, i.e. a corresponding semiconductor device pad 12.

The pin or pad/connection 12 may basically be any pin or pad/connection 12 of the semiconductor device 2 to be tested, e.g., a pin or pad/connection 12 to which, in a normal operation or a normal operation mode, respectively, of the semiconductor device 2—instead of the above-mentioned test signal—corresponding (user) data signals are applied (i.e. a data pin or pad), or corresponding address, clock, or control signals (i.e. an address, clock, or control pin or pad).

Correspondingly similar as the above-mentioned test signal, the interference signals output by the pattern generator 3 at the above-mentioned test lines 6, 8 are also transmitted to corresponding further pins of the semiconductor device 2, and from there—via corresponding bonding wires—to corresponding further connections 11, 13 of the semiconductor device 2, i.e. corresponding further semiconductor device pads 11, 13.

The further pins or pads/connections 11, 13 may—also—basically be any pins or pads/connections 12 of the semiconductor device 2, e.g., pins or pads/connections 11, 13 to which, in a normal operation or a normal operation mode, respectively, of the semiconductor device 2—instead of the above-mentioned interference signals—corresponding (user) data signals or corresponding address, clock, or control signals are applied (i.e. data, address, clock, or control pins or pads).

The above-mentioned further pins or pads/connections 11, 13 to which the above-mentioned interference signals are applied, are pins or pads/connections 11, 13 that are directly adjacent to the respective pin or pad/connection 12 of the semiconductor device 2 to be tested.

The semiconductor device 2 to be tested is adapted to be operated in—at least—two different modes, namely in the above-mentioned normal operation mode, and in a specific test mode that will be explained in more detail in the following.

In the normal operation mode, corresponding (user) data signals (or corresponding address, clock, or control signals) applied to the pins or pads/connections 11, 12, 13 of the semiconductor device 2 are, via corresponding lines 11a, 12a, 13a connected with the pads/connections 11, 12, 13, transmitted to corresponding receiver circuits 17, 18, 19. The receiver circuits 17, 18, 19 may, for instance, be constructed and equipped correspondingly similar or identical to conventional semiconductor device receiver circuits.

By using the receiver circuits 17, 18, 19, for instance, a corresponding analog-digital conversion of the signals present at the lines 11a, 11b, 11c may be performed, and/or a corresponding signal level conversion and/or signal amplification, etc. As receiver circuits 17, 18, 19, receiver circuits 17, 18, 19 including, for instance, corresponding, cross-coupled p- or n-channel field effect transistors may be used, or any other receiver circuits.

The output signals output by the receiver circuits 17, 18, 19 at corresponding lines 17a, 18a, 19a may—correspondingly similar or identical as with conventional semiconductor devices—be transmitted to corresponding flip flops 23, 24, 25 (in particular e.g., to the “Set” (“S”) inputs thereof).

By using the flip flops 23, 24, 25, a buffering of the signals output by the receiver circuits 17, 18, 19 at the lines 17a, 18a, 19a can be achieved, and a temporally coordinated relaying of the signals to corresponding flip flop output lines 23a, 24a, 25a, depending on a clock signal CLK (generated, for instance, from an external clock signal) present at corresponding clock inputs of the flip flops 23, 24, 25 and supplied via a clock line 33.

The flip flops 23, 24, 25 may be constructed and equipped correspondingly similar or identical as flip flops used with conventional semiconductor devices and connected to corresponding receiver circuits, or in any other manner.

As results from FIG. 2, the signals output by the flip flops 23, 24, 25 at the above-mentioned flip flop output lines 23a, 24a, 25a are—other than with conventional semiconductor devices—not transmitted directly to means provided in the semiconductor device core 32 (or further means upstream thereof and not illustrated here), but are—initially—transmitted to corresponding multiplexers 26, 27, 28 (or, more exactly: to corresponding data inputs of the multiplexers 26, 27, 28).

In other words, the input interface circuits (e.g., the above-mentioned receiver circuits 17, 18, 19, and/or the above-mentioned flip flops 23, 24, 25) provided on the semiconductor device 2 are thus not directly connected with the semiconductor device core 32 (i.e. the “circuit core”), but—indirectly—via the above-mentioned multiplexers 26, 27, 28.

The frequency of a clock signal used internally in the semiconductor device core 32, or the data rate used internally in the semiconductor device core 32, respectively, may be lower than the frequency of the clock signal CLK present at the clock line 33 and supplied to the flip flops 23, 24, 25, or lower than the above-mentioned data rate of the test and/or interference signals present at the test lines 6, 7, 8 (e.g., by more than ⅓ or ½ lower, e.g., only ¼ as high, etc.).

Depending on whether the semiconductor device 2 is operated in the above-mentioned normal operation mode or in the above-mentioned test mode, the signals present at the flip flop output lines 23a, 24a, 25a are connected through to corresponding “normal operation” data outputs of the multiplexers 26, 27, 28 (and thus via corresponding lines 26a, 27a, 28a to the semiconductor device core 32 (or the means provided there in correspondence with conventional semiconductor devices, e.g., DRAM memory cells, a CPU, or FIFO memories connected upstream the core 32, etc., etc.)), or to corresponding “test operation” data outputs of the multiplexers 26, 27, 28, and thus via corresponding lines 26b, 27b, 28b to corresponding demultiplexers 29, 30, 31 (or more exactly: corresponding “test operation” data inputs of the demultiplexers 29, 30, 31 (cf. below)).

The state of the multiplexers 26, 27, 28 may be controlled by a control signal present at a control line 34 and transmitted to corresponding control inputs of the multiplexers 26, 27, 28.

In a first state of the signal present at the control line 34 (e.g., “logic low” (oralternatively: “logic high”))—i.e. in the “normal operation mode”—the data inputs of the multiplexers 26, 27, 28 may, for instance, be connected with the “normal operation” data outputs of the multiplexers 26, 27, 28 (i.e. the above-mentioned lines 26a, 27a, 28a) and be separated from the “test operation” data outputs of the multiplexers 26, 27, 28 (i.e. the lines 26b, 27b, 28b).

On the other hand, in a second—inverse—state of the signal present at the control line 34 (e.g., “logic high” (oralternatively: “logic low”))—i.e. in the “test operation mode”—the data inputs of the multiplexers 26, 27, 28 may be separated from the “normal operation” data outputs of the multiplexers 26, 27, 28 (i.e. the above-mentioned lines 26a, 27a, 28a), and be connected with the “test operation” data outputs of the multiplexers 26, 27, 28 (i.e. the lines 26b, 27b, 28b).

As has already been indicated above, corresponding “test operation” data inputs of the demultiplexers 29, 30, 31 are, via corresponding lines 26b, 27b, 28b, connected to corresponding “test operation” data outputs of the multiplexers 26, 27, 28.

Furthermore—as results further from FIG. 2—corresponding “normal operation” data inputs of the demultiplexers 29, 30, 31 are, via corresponding lines 29b, 30b, 31b, connected to the semiconductor device core 32 (or to (further) means provided there in correspondence with conventional semiconductor devices, e.g., DRAM memory cells, a CPU, or FIFO memories connected downstream the core 32, etc., etc.).

The data outputs of the demultiplexers 29, 30, 31 are, via corresponding lines 29a, 30a, 31a, connected to corresponding driver circuits 20, 21, 22.

Output signals provided by the semiconductor device core 32 (or the further means provided there, respectively) are thus—other than with conventional semiconductor devices—not transmitted directly to the driver circuits 20, 21, 22, but initially transmitted to the above-mentioned demultiplexers 29, 30, 31.

In other words, the output interface circuits provided on the semiconductor device 2 (e.g., the above-mentioned driver circuits 20, 21, 22) are thus not connected directly with the semiconductor device core 32, but—indirectly—via the above-mentioned demultiplexers 29, 30, 31.

Depending on whether the semiconductor device 2 is operated in the above-mentioned normal operation mode or in the above-mentioned test mode, the signals present at the “normal operation” data inputs of the demultiplexers 29, 30, 31 (i.e. the above-mentioned lines 29b, 30b, 31b)—i.e. the signals provided by the semiconductor device core 32—are relayed to the data outputs of the demultiplexers 29, 30, 31 (and thus, via the lines 29a, 30a, 31a to the driver circuits 20, 21, 22), or the signals present at the “test operation” data inputs of the demultiplexers 29, 30, 31 (i.e. the above-mentioned lines 26b, 27b, 28b)—i.e. the signals provided by the above-mentioned multiplexers 26, 27, 28.

The state of the demultiplexers 29, 30, 31 can—like the state of the multiplexers 26, 27, 28—be controlled by the control signal present at the control line 34 and supplied to corresponding control inputs of the demultiplexers 29, 30, 31.

In the above-mentioned first state of the signal present at the control line 34 (e.g., “logic low” (oralternatively: “logic high”))—i.e. in the “normal operation mode”—, the “normal operation” data inputs of the demultiplexers 29, 30, 31, i.e. the lines 29b, 30b, 31b, may, for instance, be connected with the demultiplexer data outputs (i.e. the above-mentioned lines 29a, 30a, 31a), and the “test operation” data inputs of the demultiplexers 29, 30, 31, i.e. the lines 26b, 27b, 28b, may be separated from the demultiplexer data outputs (i.e. the above-mentioned lines 29a, 30a, 31a).

On the other hand, in the above-mentioned second—inverse—state of the signal present at the control line 34 (e.g., “logic high” (oralternatively: “logic low”))—i.e. in the “test operation mode”—, the “normal operation” data inputs of the demultiplexers 29, 30, 31, i.e. the lines 29b, 30b, 31b, may be separated from the demultiplexer data outputs (i.e. the above-mentioned lines 29a, 30a, 31a), and the “test operation” data inputs of the demultiplexers 29, 30, 31, i.e. the lines 26b, 27b, 28b, may be connected with the demultiplexer data outputs (i.e. the above-mentioned lines 29a, 30a, 31a).

The driver circuits 20, 21, 22 that are, via the above-mentioned lines 29a, 30a, 31a, connected with the data outputs of the demultiplexers 29, 30, 31, may, for instance, be constructed and equipped correspondingly similar or identical to conventional semiconductor device driver circuits.

By using the driver circuits 20, 21, 22, a corresponding signal level conversion and/or signal amplification, etc. of the signals present at the lines 29a, 30a, 31a and supplied to corresponding inputs of the driver circuits 20, 21, 22 may, for instance, be performed, etc. As driver circuits 20, 21, 22, corresponding driver circuits 20, 21, 22 including a pull-up and a pull-down transistor may, for instance, be used, or any other driver circuits.

The signals output at the outputs of the driver circuits 20, 21, 22 are—as conventionally and as illustrated in FIG. 2—transmitted to (additional) pads or connections 14, 15, 16 of the semiconductor device 2, which are connected with the driver circuits 20, 21, 22, and from there—via corresponding bonding wires—to corresponding (additional) pins of the semiconductor device 2.

The above-mentioned additional pins or pads/connections 14, 15, 16 may basically be any pins or pads/connections 14, 15, 16 of the semiconductor device 2, e.g., pins or pads/connections 14, 15, 16 at which, in the above-mentioned normal operation mode of the semiconductor device 2, (user) data signals—generated from the signals provided by the above-mentioned semiconductor device core 32—are output (or corresponding address, clock, or control signals (i.e. data, address, clock, or control pins or pads)).

For switching between the “normal operation mode” and the “test operation mode”—as already indicated above—, the signal present at the control line 34 is placed from the above-mentioned first state to the above-mentioned—inverse—second state (e.g., from “logic low” to “logic high” (or alternatively vice versa: from “logic high” to “logic low”)).

To this end—with a first variant of the present embodiment—the control line 34 may, for instance, be connected to a separate pad of the semiconductor device 2 which is, via a corresponding bonding wire, connected to a separate semiconductor device pin to which a corresponding—either “logic high” or “logic low”—control signal can be applied and be transmitted to the control inputs of the multiplexers 26, 27, 28 and demultiplexers 29, 30, 31.

In a second variant of the present embodiment, the semiconductor device 2 may be placed from the “normal operation mode” to the “test operation mode” (and later back to the “normal operation mode” again) in that a specific command (“key”) or pattern is applied to a plurality of—anyway existing—pins or pads of the semiconductor device 2 (i.e. corresponding data, address, and/or control pins or pads), by which a change to be performed from the “normal operation mode” to the “test operation mode” (and back to the “normal operation mode”) is signalized to the semiconductor device 2.

In reaction to receiving the key or pattern, the semiconductor device 2 places the signal present at the control line 34 from the above-mentioned first state to the above-mentioned second—inverse—state (e.g., from “logic low” to “logic high”—and back to the above-mentioned first state (e.g., from “logic high” to “logic low”, etc.)).

In the “test operation mode”, the above-mentioned test signal output by the pattern generator 3—and possibly additionally impacted with jitter—and present at the test line 7 (and possibly additionally the interference signals that are, for instance, present at the test lines 6, 8) are, via the pad/the connection 11 (or the pads/connections 11, 12, 13) transmitted to the receiver circuit 18 (or the receiver circuits 17, 18, 19), and from there to the flip flop 24 (or the flip flops 23, 24, 25), and—after applying a corresponding clock signal CLK (generated, for instance, from an external clock signal) to the clock line 33—to the multiplexer 27 (or the multiplexers 26, 27, 28), the demultiplexer 30 (or the demultiplexers 29, 30, 31), the driver circuit 21 (or the driver circuits 20, 21, 22), the connection 15 (or the connections 14, 15, 16), and from there e.g., to a test line 9 connected with the connection 15—e.g., via the above-mentioned bonding wire and the corresponding semiconductor device pin—(or alternatively to a plurality of test lines connected with the connections 14, 15, 16) (“test path”).

As results from FIG. 1, the signal output by the driver circuit 21 at the test line 9—and generated in reaction to the test signal input in the semiconductor device 2 at the test line 7—(i.e. the bit sequence/test data corresponding to the bit sequence/test data input in the semiconductor device 2 at the test line 7) is supplied to the above-mentioned test device 4.

By using the test device 4, the test data/bit sequence output by the pattern generator 3 at the test line 7 are/is compared with the test data/bit sequence received at the test line 9 (it is, in particular, determined whether a transmitted “1” was correctly received as “1” (or erroneously as “0”), and a transmitted “0” was correctly received as “0” (or erroneously as “1”)).

Thus, the bit error rate, i.e. the number of bit errors occurring per time unit, can be determined and indicated by the test device 4.

The above-mentioned test may be repeated several times, as the case may be, e.g., with respectively different test signal data rates, and/or with test signals that are differently strongly impacted with additional jitter, and/or with or without respective interference signals, and/or with differently strong interference signals, etc.

Additionally to the above-mentioned bit error rate determination, the exact time progression of the signal present at the test line 9 may also be determined by the test device 4 (wherein the test device 4 is adapted to indicate, for instance, the respective data eye resulting for the received test signal, and to subject it to a more precise analysis, etc.).

With further variants of the invention, the above-mentioned multiplexers 26, 27, 28 or demultiplexers 29, 30, 31 may also be positioned at respective other places in the semiconductor device 2 than illustrated above by way of example with respect to FIG. 2, so that respectively other test paths will result than explained above.

The multiplexers 26, 27, 28 may, for instance, also be positioned between the receiver circuits 17, 18, 19 and the flip flops 23, 24, 25 instead between the flip flops 23, 24, 25 and the semiconductor device core 32 (so that, for instance, the following test path will result: connections 11, 12, 13, receiver circuits 17, 18, 19, multiplexers 26, 27, 28, demultiplexers 29, 30, 31, connections 14, 15, 16).

Parts of the logic/means provided in the above-mentioned semiconductor device core 32 may also be included in the respective test path, or further means connected upstream or downstream the core 32 and not illustrated here, e.g., the above-mentioned (input-side) FIFO memories, or the above-mentioned further (output-side) FIFO memories, etc. (i.e. logic/means that is/are—in the narrower sense—not to be attributed to the semiconductor device core 32). By using the above-mentioned FIFO memories, a data width conversion and/or data buffering may, for instance, be achieved, e.g., a data width conversion/buffering of the data to be input in the core 32 at the input side/to be output from the core 32 at the output side.

The multiplexers 26, 27, 28 may, for instance, instead between the flip flops 23, 24, 25 and the semiconductor device core 32, also be provided between the above-mentioned semiconductor device core logic parts—to be comprised by the test path—or the above-mentioned FIFO memories, respectively, and the (remaining) logic parts/semiconductor memory device core 32 (i.e. the semiconductor device core in the narrower sense), and/or the demultiplexers 29, 30, 31, instead between the driver circuits 20, 21, 22 and the semiconductor device core 32, for instance, also between the above-mentioned semiconductor device core logic parts—to be comprised by the test path—or the above-mentioned (further) FIFO memories, respectively, and the (remaining) logic parts/semiconductor device core 32 (i.e. the semiconductor device core in the narrower sense), etc.

In addition to the—actual—FIFO memories provided in the semiconductor device core 32, or connected upstream/downstream of the core 32 in the narrower sense, respectively, corresponding “dummy” FIFO memories may be provided on the semiconductor memory 2, which may be constructed and equipped identically to the actual FIFO memories. These “dummy” FIFO memories may be comprised in the above-mentioned test path. Then, the following path will, for instance, result as test path: connections 11, 12, 13, receiver circuits 17, 18, 19, flip flops 23, 24, 25, multiplexers 26, 27, 28, FIFO memory or dummy FIFO memory, demultiplexers 29, 30, 31, connections 14, 15, 16, etc.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for testing an integrated circuit having a semiconductor device comprising:
defining a normal operation mode and a test operation mode;
transmitting a signal present at a connection of the semiconductor device to a circuit core of the semiconductor device in the normal operation mode; and
transmitting a test signal present at the connection of the semiconductor device to a further connection of the semiconductor device instead to the circuit core of the semiconductor device in the test operation mode.

2. The method of claim 1, comprising:
using at least one switching device for transmitting the signal or test signal, respectively, either to the circuit core or to the further connection.

3. The method of claim 2, comprising using a multiplexer and/or a demultiplexer as the switching device.

4. The method of claim 1, comprising wherein, in the test operation mode, transmitting the test signal to the further connection of the semiconductor device via at least one interface circuit.

5. The method of claim 4, wherein the interface circuit comprises a receiver circuit.

6. The method of claim 4, wherein the interface circuit comprises a flip flop.

7. The method of claim 4, wherein the interface circuit comprises a driver circuit.

8. The method of claim 1, comprising using a bit sequence as test signal.

9. The method of claim 1, comprising outputting the test signal via a test device; and transmitting the test signal to the connection of the semiconductor device.

10. The method of claim 9, comprising transmitting the test signal transmitted from the connection to the further connection of the semiconductor device to the device, to the test device or to a further test device.

11. The method of claim 10, comprising:
comparing a bit sequence of the test signal output by the test device with a test signal bit sequence transmitted to the test device or to the further test device.

12. The method of claim 9, comprising outputting via the test device, in addition to the test signal, at least one interference signal interfering with the test signal.

13. An integrated circuit having a semiconductor device comprising:
a connection;
a circuit core;
a switching device; and
where in a normal operation mode a signal present at the connection is transmitted to the circuit core of the semiconductor device, and where in a test mode of operation the the switching device is configured for transmitting a test signal present at the connection to a further connection of the semiconductor device instead to the circuit core of the semiconductor device.

14. The integrated circuit of claim 13, comprising where the switching device is a multiplexer.

15. The integrated circuit of claim 13, comprising where the switching device is connected between an input interface circuit, and the circuit core of the semiconductor device.

16. The integrated circuit of claim 15, comprising wherein the input interface circuit comprises a receiver circuit.

17. The integrated circuit of claim 15, comprising wherein the input interface circuit comprises a flip flop.

18. The integrated circuit of claim 13, comprising a further switching device.

19. The integrated circuit of claim 13, comprising wherein the further switching device is a demultiplexer.

20. The integrated circuit of claim 13, comprising wherein the further switching device is connected between an output interface circuit, and the circuit core of the semiconductor device.

21. The integrated circuit of claim 20, wherein the output interface circuit comprises a driver circuit.

22. An integrated circuit having a semiconductor device comprising:
a connection;
a core, where in a normal operation mode a signal present at the connection is transmitted to the core;
an output interface circuit; and
a switch, where in test operation mode the switch is configured to transmit a test signal present at the connection to the output interface circuit.

23. The integrated circuit of claim 22, comprising:
an input interface circuit, where the signal is transmitted to the core via the input interface circuit.

24. The integrated circuit of claim 23, where the input interface circuit comprises a receiver circuit and a buffer.

25. The integrated circuit of claim 24, where the buffer comprises at least one flip-flop.

26. The integrated circuit of claim 24, where the switch is coupled between the buffer and the core.

27. The integrated circuit of claim 24, where the switch is coupled between the receiver circuit and the buffer.

28. The integrated circuit of claim 22, where the switch comprises at least one multiplexer.

29. The integrated circuit of claim 22, where the output interface circuit comprises at least one demultiplexer.

30. The integrated circuit of claim 22, where the output interface circuit comprises at least one driver.

31. The integrated circuit of claim 22, comprising:
a control signal, configured to change the switch between a normal operation mode and a test operation mode.

32. The integrated circuit of claim 31, where the control signal comprises a test pattern.
